(19) United States
(12) Patent Application Publication
(10) Pub. No.: US 2014/0225087 A1
(43) Pub. Date: Aug. 14, 2014

(54) ORGANIC LIGHT-EMITTING DISPLAY WITH SOLAR CELL

(71) Applicants: WINTEK CORPORATION, TAICHUNG CITY (TW); WINTEK (CHINA) TECHNOLOGY LTD., DONGGUAN CITY (CN)

(72) Inventors: Chong-Yang Fang, Taichung City (TW); Ping-Yeng Chen, Taichung City (TW); Hen-Ta Kang, Taichung City (TW); Chia-Hsiung Chang, Tainan City (TW)

(73) Assignees: WINTEK CORPORATION, TAICHUNG CITY (TW); WINTEK (CHINA) TECHNOLOGY LTD., DONGGUAN CITY (CN)

(21) Appl. No.: 14/174,860

(22) Filed: Feb. 7, 2014

(30) Foreign Application Priority Data
Feb. 8, 2013 (TW) 102105313

(51) Int. Cl. H01L 27/32

(52) U.S. Cl. CPC H01L 27/3227
USPC 257/40

(57) ABSTRACT

An organic light-emitting display with a solar cell includes a first substrate, a second substrate, a plurality of organic light-emitting units, and at least one solar cell unit. The second substrate is disposed oppositely to the first substrate and has an inside surface facing the first substrate. The organic light-emitting units are arranged as an array on the inside surface of the second substrate. The second substrate has non-emission regions positioned between any two adjacent light-emitting units. The solar cell unit is disposed in one of the non-emission region for receiving the light generated by the solar cell units to produce current.

### BACKGROUND OF THE INVENTION

1. Field of the Invention

The present invention relates to an organic light-emitting display (OLED), and more particularly, to an organic light-emitting display with solar cell.

2. Description of the Prior Art

An organic light-emitting display adopts organic light-emitting materials in an active array display panel, which is controlled by the driving current to achieve the effect of different brightness. The organic light-emitting display has advantages such as power saving, low limitation of viewing angle, lower manufacturing cost, a shorter response time, a wider range of operated temperature and flexible miniaturization in accordance with the hardware. As a result, the organic light-emitting display has great development potential in a flat display device. However, most organic light-emitting materials have high refractive indices, resulted in that the critical angle of total internal reflection is very small for the light generated by themselves, which means the chance or proportion of occurring total internal reflection of the light is rather high such that a certain portion of light will not emit out the organic light-emitting display to display images. Accordingly, the emission efficiency of a conventional organic light-emitting display is limited. On the other hand, that a part of light cannot emit out the display panel because of total internal reflection also induces the issue of energy waste.

### SUMMARY OF THE INVENTION

It is one of the objectives of the present invention to provide an organic light-emitting display with solar cell, wherein the organic light-emitting display includes at least one solar cell unit disposed between two organic light-emitting units. The solar cell unit can absorbing light produced inside the display panel to thereby generate current and achieve the effect of saving power consumption.

To achieve the purposes described above, an embodiment of the present invention provides an organic light-emitting display with solar cell, wherein the organic light-emitting display includes a first substrate, a second substrate, a plurality of organic light-emitting units and at least one solar cell unit. The second substrate and the first substrate are disposed oppositely, and the second substrate has an inside surface facing the first substrate. The organic light-emitting units are arranged as an array on the inside surface of the second substrate, and a non-emission region is defined between any two organic light-emitting units adjacent to each other. The solar cell unit is disposed in one of the non-emission regions on the inside surface of the second substrate for receiving light generated by the organic light-emitting units to produce current.

It is an advantage of the present invention that at least one solar cell unit is disposed between the organic light-emitting units that the solar cell unit can be used to absorb the light not emitting out the display when it displaying images. The solar cell unit can generate current so as to avoid energy waste and further save the whole energy consummation of the organic light-emitting display.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic sectional-view of an organic light-emitting display with solar cell according to a first embodiment of the present invention.

FIG. 2 is a schematic sectional-view of an organic light-emitting display with solar cell according to a second embodiment of the present invention.

FIG. 3 is a schematic sectional-view of an organic light-emitting display with solar cell according to a third embodiment of the present invention.

FIG. 4 is a schematic sectional-view of an organic light-emitting display with solar cell according to a fourth embodiment of the present invention.

### DETAILED DESCRIPTION

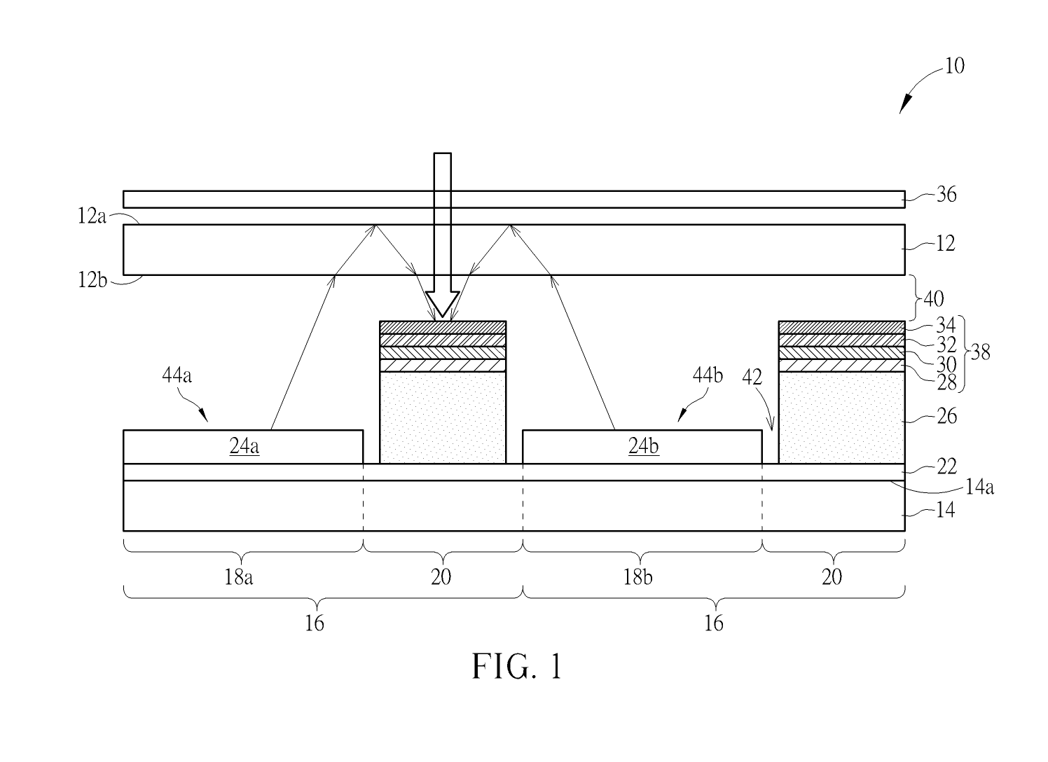

Referring to FIG. 1, FIG. 1 is a schematic sectional-view of an organic light-emitting display with solar cell according to a first embodiment of the present invention. The organic light-emitting display 10 with solar cell of the present invention includes a first substrate 12 and a second substrate 14, wherein the second substrate 14 and the first substrate 12 are disposed oppositely. As shown in FIG. 1, the second substrate 14 is disposed at a bottom side of the first substrate 12 and the second substrate 14 has an inside surface 14a facing the bottom surface of the first substrate 12, which is the inside surface 12b of the first substrate 12. The second substrate 14 includes a plurality of pixels 16 defined thereon, wherein the pixels 16 are arranged as an array. The pixels 16 used herein may also refer to the sub-pixels used to produce any primary color lights or any other color lights for composing display images, but not limited thereto. Each pixel 16 includes an emission region (marked as 18a, 18b for example) and a non-emission region 20, wherein the “non-emission regions 20” are relative to the emission regions 18a, 18b because there is substantially no organic light-emitting materials disposed in the non-emission regions 20. In other embodiments, the non-emission regions 20 maybe regarded as not belong to apart of the pixels 16 but as disposed between two adjacent pixels 16.

Taking that the present invention organic light-emitting display 10 is a top emission type active organic light-emitting display as an example, there are a plurality of driving devices, such as switch devices and capacitors, disposed on the second substrate 14, wherein the switch devices may be thin film transistors for instance. These driving devices are shown as the driving device layer 22 in FIG. 1 as the representative. In this embodiment, the switch devices may be disposed within the non-emission regions 20 and on the inside surface 14a of the second substrate 14. However, in other embodiments, the switch devices may be disposed in the emission regions 18a, 18b of the second substrate 14. Furthermore, on the inside surface 14a of the second substrate 14, there are a plurality of organic light-emitting units (marked as 44a and 44b in FIG. 1) disposed in the emission regions 18a, 18b respectively. For example, each of the organic light-emitting units 44a, 44b in FIG. 1 is electrically connected to the switch device of the corresponding pixel 16. When the switch device is switched on, the corresponding organic light-emitting unit 44a or 44b will generate light in order to display images. Each of the organic light-emitting units 44a, 44b may include a single layer or multiple layers of organic light-emitting materials respectively. Since the organic light-emitting units 44a, 44b are disposed in a corresponding pixel 16 respectively, the organic light-emitting units 44a, 44b are arranged as an array, too. In this embodiment, each pixel 16 is used for producing one kind of light of three primary color lights, which means each pixel 16 is used for producing one of red light, blue light and green light so as to provide colorful images with gray levels, for example. As a result, any two adjacent organic light-emitting units 44a, 44b may include non-identical organic materials for generating different color lights. As an example, the organic light-emitting unit 44a may include a red organic light-emitting material layer 24a for producing red light, while the organic light-emitting unit 44b may include a green organic light-emitting material layer 24b for producing green light.

The present invention organic light-emitting display 10 further includes at least one solar cell unit 38 disposed in at least one non-emission region 20. In a preferable embodiment, the present invention organic light-emitting display 10 includes a plurality of solar cell units 38 and the solar cell units 38 are disposed in the non-emission regions 20 between any two adjacent organic light-emitting units 44a, 44b respectively, but not limited thereto. The amount of the solar cell units 38 may be varied and designed in accordance with practical requirements. In addition, the solar cell units 38 include a plurality of material layers, such as having a structure of multi-layer, and may include transparent materials and/or non-transparent materials. In a preferable embodiment, the solar cell units 38 may include organic materials. Since the organic light-emitting display 10 of this embodiment is a top emission type display, the solar cell units 38 include a second electrode layer 34, a transport layer 32, an absorption layer 30 and a first electrode layer 28 in order from top to bottom on the top surface (the inside surface 14a) of the second substrate 14. In other words, the second electrode layer 34, the transport layer 32, the absorption layer 30 and the first electrode layer 28 are disposed from a side near the first substrate 12 to a side near the second substrate 14 in order. In a preferable embodiment, the first electrode layer 28 is a reflective electrode layer and includes reflective material, such as metal material, and the second electrode layer 34 is a transparent electrode layer (or a light-permitting electrode layer) that includes transparent material, such as indium tin oxide (ITO), but not limited thereto. However, it should be noted that the relative sizes, patterns and shapes of these layers of the solar cell units 38 are not limited to those shown in FIG. 1.

In a preferable embodiment, the present invention organic light-emitting display 10 further includes a plurality of banks 26, each of which is respectively disposed in one of the non-emission regions 20 on the inside surface 14 of the second substrate 14a, between any two adjacent organic light-emitting units 44a, 44b. Moreover, each bank 26 is disposed between one of the solar cell unit 38 and the second substrate 14. When manufacturing the organic light-emitting display 10, a plurality of banks 26 may be first formed on the inside surface 14a of the second substrate 14, followed by forming organic light-emitting material layers with different colors on the inside surface 14a of the second substrate 14 by evaporation processes in collocation with shadow masks so as to prevent a color of the organic light-emitting material from being evaporated onto a predetermined region of another color of organic light-emitting material layer resulted from misalignment of the shadow masks or other factors. The bank 26 may include transparent photoresist material for example. In addition, the solar cell units 38 disposed on the banks 26 may be formed on the second substrate 14 before forming the organic light-emitting material layers of the organic light-emitting units 44a, 44b. However, based on various considerations, the solar cell units 38 may also be formed after the organic light-emitting material layers of the organic light-emitting units 44a, 44b are all fabricated. It should be noted that the formation sequence of the film layers of the organic light-emitting units 44a, 44b and the solar cell units 38 is not limited to the above description. For example, because both the organic light-emitting units 44a, 44b and the solar cell units 38 include multiple film layers respectively, the formation processes of the several film layers of the organic light-emitting units 44a, 44b and the solar cell units 38 may be carried out alternately. Furthermore, since the solar cell units 38 are disposed above the banks 26, based on the horizontal level parallel to the surface of the second substrate 14, the position of the solar cell units 38 is higher than that of the organic light-emitting units 44a, 44b. It should be noted that a transparent medium 40 is further disposed between the solar cell units 38 and the first substrate 12 or between the organic light-emitting units 44a, 44b and the first substrate 12 in a preferable embodiment, wherein the transparent medium 40 may be gas or including refraction matching material with a refractive index between that of the first substrate 12 and that of the organic light-emitting units 44a, 44b. The functionality of the transparent medium 40 is to reduce occurrence of total internal reflection. Moreover, a gap 42 (or called as a spacing) exists between each solar cell unit 38 and an adjacent organic light-emitting material layer of the organic light-emitting unit 44a or 44b, such as the red organic light-emitting material layer 24a or the green organic light-emitting material layer 24b. In addition, a passivation layer or a planarization layer (not shown) maybe optionally disposed on the surface of the solar cell units 38 and the organic light-emitting units 44a, 44b, but not limited thereto. In another aspect, a circular polarizer 36 may be optionally disposed on the outside surface 12a of the first substrate 12 so as to improve the problem of light reflection from environmental light source and thereby to provide clearer images.

The arrows with thin line shown in FIG. 1 represent the possible passing path of lights generated by the organic light-emitting units 44a, 44b. Taking the emission region 18a as an example, a part of the light generated by the emission region 18a will pass through the first substrate 12 and pass out the organic light-emitting display 10 for displaying images, but another part of the light will be reflected back to the space between the first substrate 12 and the second substrate 14, such as the transparent medium 40, resulted from total internal reflection when it progress to the outer surface of the first substrate 12. When the reflected light passes into one of the solar cell units 38, it will be absorbed by the solar cell unit 38 and transformed into photo-current, then be further reutilized by the organic light-emitting display 10 for reducing the total power consumption of the organic light-emitting display 10. In FIG. 1, a thick hollow arrow represents the possible passing path of the light from the external environment light source. The light from the external environment light source may pass into the organic light-emitting display 10 through the first substrate 12 and then into the solar cell unit 38, after passing through the transparent medium 40, to be absorbed by the solar cell units 38 and transformed into electric energy, which can be reutilized. In addition, when the light progressing between the first substrate 12 and the second substrate 14 reaches the first electrode layer 28 including reflective material, it may also be reflected by the first electrode layer 28 to the absorption layer 30 and be reutilized by the way of being transformed into electric energy. Therefore, the present invention organic light-emitting display 10 reutilizes not only the light generated by the organic light-emitting units 44a, 44b and not emitting out the organic light-emitting display 10 but also the environment light entering the organic light-emitting display 10 to produce electric energy, so as to reduce the total power consumption thereof.

The organic light-emitting display with solar cell of the present invention is not limited by the aforementioned embodiment, and may have other different preferred embodiments and variant embodiments. To simplify the description, the identical components in each of the following embodiments are marked with identical symbols. For making it easier to compare the difference between the embodiments, the following description will detail the dissimilarities among different embodiments and the identical features will not be redundantly described.

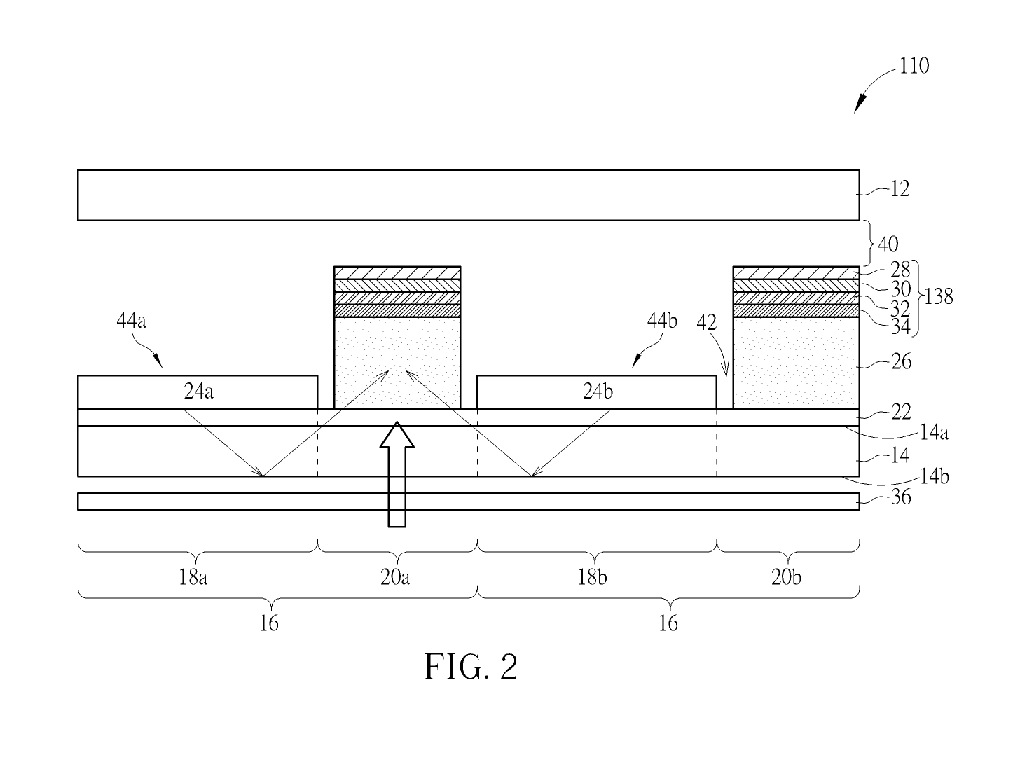

Referring to FIG. 2, FIG. 2 is a schematic sectional-view of an organic light-emitting display with solar cell according to a second embodiment of the present invention. Different from the previous embodiment, the organic light-emitting display 110 of this embodiment is a bottom emission type active organic light-emitting display, thus the outside surface 14b of the second substrate 14 is the light emitting side of the organic light-emitting display 110 for displaying images. Furthermore, the arranging order of the multiple film layers of the solar cell units 138 of this embodiment is different from the previous embodiment. On the surface of the bank 26, the second electrode layer 34, the transport layer 32, the absorption layer 30 and the first electrode layer 28 are disposed in order from bottom to top, which means the second electrode layer 34, the transport layer 32, the absorption layer 30 and the first electrode layer 28 are disposed in order from a side near the second substrate 14 to a side near the first substrate 12. The first electrode layer 28 is preferably a reflective electrode layer and the second electrode layer 34 is preferably a transparent electrode layer. In addition, the circular polarizer 36 is disposed on the outside surface 14b of the second substrate 14. The arrows with thin line in FIG. 2 represent the passing paths of light generated by the organic light-emitting units 44a, 44b. In consideration with the organic light-emitting units 44a, 44b based on current organic light-emitting material, about 20% to 30% of light generated by the organic light-emitting units 44a, 44b will pass through the second substrate 14 and pass out the organic light-emitting display 110 to display images, while the rest part of light (about 70% of light) will not emit out the second substrate 14 because of total internal reflection. The reflected light will pass through the second substrate 14 again and then the banks 26 to enter the solar cell units 138, as shown by the arrows with thin line. A part of the reflected light may be reflected with several times to diffuse with lateral directions in the second substrate 14 and then enter the solar cell unit 138 in another pixel 16. For example, the light generated by the organic light-emitting unit 44a in the emission region 18a may first enter the second substrate 14 and be reflected because of the total internal reflection when it reaches the outer surface of the second substrate 14 (such as the outside surface 14b), followed by being reflected repeatedly in the second substrate 14. Then, it may progress to the emission region 18b or non-emission region 20b to emit out the second substrate 14 through the inside surface 14a and enter the solar cell unit 138 in the non-emission regions 20b after passing through the bank 26. The thick hollow arrow shown in FIG. 2 represents the possible passing path of the light from the environment light source. The light from the environment may enter the organic light-emitting display 110 through the second substrate 14, and then pass through the bank 26 to progress to the solar cell units 138. As a result, the environment light may also be utilized and absorbed by the solar cell units 138 to be transformed into electric energy. On the other hand, the part of environment light not absorbed by the solar cell units 138 may keep on progressing to the first electrode layer 28 and be reflected back to the transport layer 32 or the absorption layer 30, thus the reflected light may also be reutilized to become electric energy.

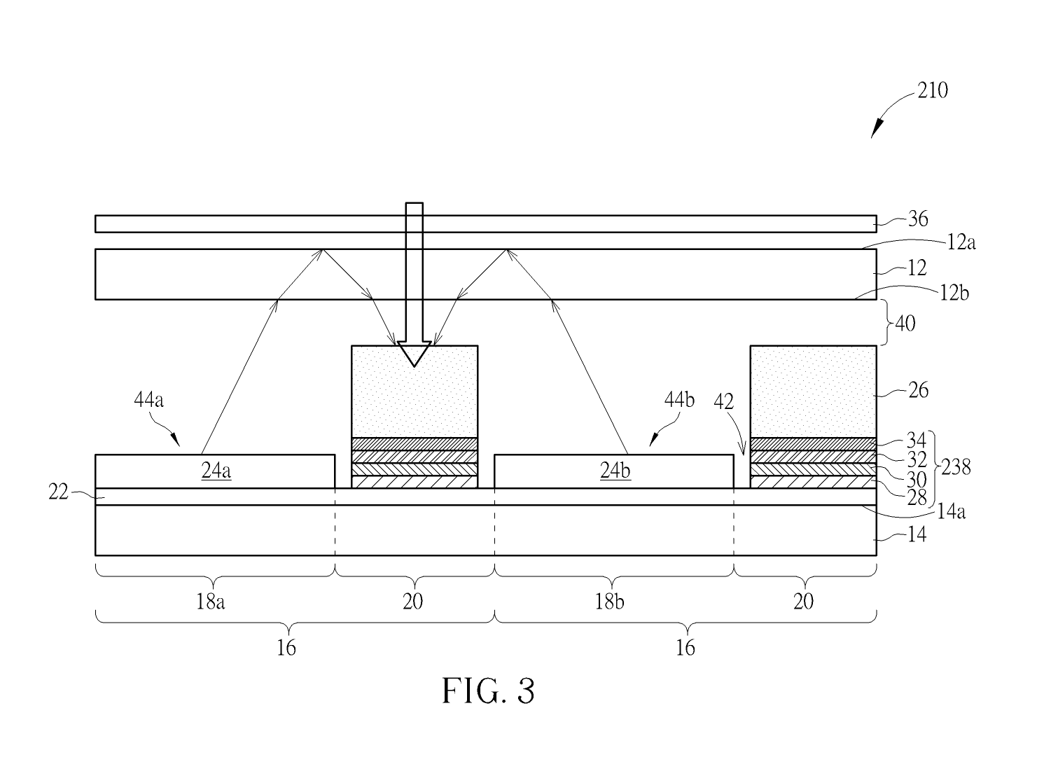

Referring to FIG. 3, FIG. 3 is a schematic sectional-view of an organic light-emitting display with solar cell according to a third embodiment of the present invention. Different from the above-mentioned embodiments, the solar cell units are disposed between the banks and the second substrate in this embodiment. As shown in FIG. 3, the organic light-emitting display 210 of the third embodiment is a top emission type active organic light-emitting display, thus a side of the first substrate 12 that faces the circular polarizer 36, which is the outside surface 12a of the first substrate 12, is the display side of the organic light-emitting display 210. The solar cell units 238 are disposed between the second substrate 14 and the banks 26 and respectively include the first electrode layer 28, the absorption layer 30, the transport layer 32 and the second electrode layer 34 in order from bottom to top, wherein the first electrode layer 28 is preferably a reflective electrode layer and the second electrode layer 34 is preferably a transparent electrode layer. In this embodiment, the solar cell units 238 is near to the second substrate 14 with driving device layer 22 disposed thereon, thus the first electrode layers 28 of the solar cell units 238 may be fabricated together with some of the driving devices (such as metal electrodes, gate lines or source lines) of the organic light-emitting units 44a, 44b. Even more, the solar cell units 238 may utilize the metal electrodes of the organic light-emitting units 44a, 44b as their first electrode layer. With such design, the first electrode layer 28 shown in FIG. 3 may be omitted.

A part of the light generated by the organic light-emitting material will emit out the organic light-emitting display 210 through the first substrate 12. Another part of the light will be reflected back to the space between the first substrate 12 and the second substrate 14 because of total internal reflection, and then pass through the transparent medium 40 and bank 26 to enter the solar cell units 238, followed by being absorbed and transformed into electric energy, whose passing path is illustrated by the arrows with thin line shown in FIG. 3. A part of the light not absorbed may keep on progressing to the first electrode layer 28 and be reflected back to the absorption layer 30 to be reutilized. The first substrate 12 also provides a function of guiding light such that it has a high possibility that the light not emitting out the first substrate 12 can progress in lateral directions in the first substrate 12 with a certain distance and then pass into the transparent medium 40 through the inside surface 12b of the first substrate 12 to enter the solar cell units 238 again and to be reutilized. Similarly, when the light from the environment light source enters the organic light-emitting display 210, it may also pass through the bank 26 and then into the solar cell units 238, which will be absorbed for producing current, as shown with the thick hollow arrow.

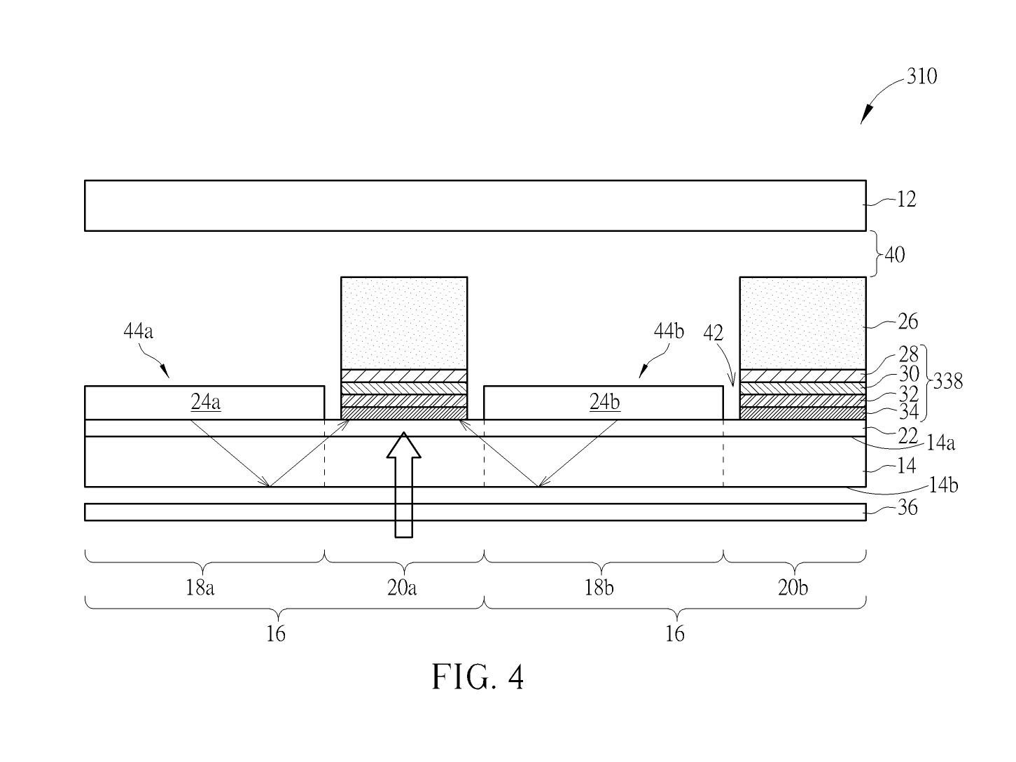

Referring to FIG. 4, FIG. 4 is a schematic sectional view of an organic light-emitting display with solar cell according to a fourth embodiment of the present invention. Different from the third embodiment, the organic light-emitting display 310 of this embodiment is a bottom emission type active organic light-emitting display and therefore the display side is at the outside surface 14b of the second substrate 14. The solar cell units 338 are disposed between the banks 26 and the second substrate 14 and respectively include the second electrode layer 34, the transport layer 32, the absorption layer 30 and the first electrode layer 28 in order from bottom to top, wherein the second electrode layer 34 is preferably a transparent electrode layer and the first electrode layer 28 is preferably a reflective electrode layer. Since the second electrode layer 34 is near to the second substrate 14 whose surface has the driving device layer 22 disposed on, the second electrode layers 34 of the solar cell units 338 and the transparent driving devices of the organic light-emitting units 44a, 44b maybe fabricated at the same time. Moreover, the solar cell units 338 may even taking the transparent driving devices (such as transparent pixel electrodes) of the organic light-emitting units 44a, 44b as their second electrode layers and therefore the second electrode layer 34 shown in FIG. 4 may be omitted for example. Similar to the second embodiment, a part of the light generated by the organic light-emitting units 44a, 44b will emit out the organic light-emitting display 310 through the second substrate 14 for displaying images, and another part of the light will not emit out the second substrate 14 because of total internal reflection. The reflected light may pass through the second substrate 14 again to enter the solar cell units 338, whose passing path is shown by the arrows with thin line. In addition, the second substrate 14 may provide a function as light guide plate, thus a part of the reflected light may also be reflected with several times to diffuse in lateral directions in the second substrate 14 and then enter the solar cell unit 338 in another pixel 16. As an example, the light generated by the organic light-emitting unit 44a in the emission region 18a may pass into the second substrate 14 but not pass out the second substrate 14 because of total internal reflection, then be reflected with several times in the second substrate 14 to progress to the emission region 18b or the non-emission region 20b, pass out the second substrate 14 through the inside surface 14a and finally enter the solar cell unit 338 in the non-emission region 20b. In addition, it is possible that the environmental light passing into the organic light-emitting display 310 through the second substrate 14 will be absorbed by the solar cell units 338, as shown with the thick hollow arrow. The light from the environment absorbed by the solar cell units 338 will be transformed into electric energy, while the part of light not absorbed will keep on progressing to the first electrode layer 28 and then be reflected back to the absorption layer 30, which may also be reutilized and transformed into electric energy.

From the above, the present invention provides an organic light-emitting display having solar cell units disposed between adjacent organic light-emitting units or adjacent pixels or disposed in the non-emission regions of pixels. As a result, when displaying images, the light not emitting out the display can be reutilized by transforming the light that enters the solar cell units into electric energy, such that the problem of energy waste can be improved and the total power consumption of the organic light-emitting display can be further reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An organic light-emitting display with solar cell, comprising:
a first substrate;
a second substrate, disposed oppositely to the first substrate, wherein the second substrate has an inside surface facing the first substrate;
a plurality of organic light-emitting units arranged as an array on the inside surface of the second substrate, a non-emission regions being disposed between any two of the organic light-emitting units adjacent to each other; and
at least one solar cell unit, disposed on the inside surface of the second substrate in one of the non-emission regions.

2. The organic light-emitting display with solar cell of claim 1, further comprising at least one bank disposed in the non-emission regions between any two of the organic light-emitting units adjacent to each other.

3. The organic light-emitting display with solar cell of claim 2, wherein the solar cell unit is disposed between the bank and the second substrate.

4. The organic light-emitting display with solar cell of claim 3, further comprising a transparent medium disposed between the bank and the first substrate.

5. The organic light-emitting display with solar cell of claim 4, wherein the transparent medium includes gas or a refraction matching material, and a refractive index of the refraction matching material is between a refractive index of the first substrate and a refractive index of the organic light-emitting units.

6. The organic light-emitting display with solar cell of claim 2, wherein the bank is disposed between the solar cell unit and the second substrate.

7. The organic light-emitting display with solar cell of claim 6, further comprising a transparent medium disposed between the solar cell unit and the first substrate.

8. The organic light-emitting display with solar cell of claim 7, wherein the transparent medium includes gas or a refraction matching material, and a refractive index of the refraction matching material is between a refractive index of the first substrate and a refractive index of the organic light-emitting units.

9. The organic light-emitting display with solar cell of claim 1, wherein the organic light-emitting display is a top emission type organic light-emitting display, and the solar cell unit includes a first electrode layer, an absorption layer, a transport layer and a second electrode layer disposed on the inside surface of the second substrate in order from a side near the second substrate to a side near the first substrate.

10. The organic light-emitting display with solar cell of claim 9, wherein the first electrode layer is a reflective electrode layer, and the second electrode layer is a transparent electrode layer.

11. The organic light-emitting display with solar cell of claim 1, wherein the organic light-emitting display is a bottom emission type organic light-emitting display, and the solar cell unit includes a first electrode layer, an absorption layer, a transport layer and a second electrode layer disposed on the inside surface of the second substrate in order from a side near the first substrate to a side near the second substrate.

12. The organic light-emitting display with solar cell of claim 11, wherein the first electrode layer is a reflective electrode layer, and the second electrode layer is a transparent electrode layer.

13. The organic light-emitting display with solar cell of claim 1, further comprising a plurality of solar cell units disposed on the inside surface of the second substrate within the non-emission regions respectively.
